(19) United States
(12) Patent Application Publication
(10) Pub. No.: US 2026/0182215 A1
(43) Pub. Date: Jun. 25, 2026

(54) DISPLAY DEVICE AND ELECTRONIC DEVICE INCLUDING THE SAME

(71) Applicant: Samsung Display Co., Ltd., Yongin-si (KR)

(72) Inventor: HYUNEOK SHIN, Yongin-si (KR)

(21) Appl. No.: 19/388,510

(22) Filed: Nov. 13, 2025

(30) Foreign Application Priority Data
Dec. 20, 2024 (KR) 10-2024-0192238

(51) Int. Cl. H10K 59/80; H10K 102/00; H10K 102/10

(52) U.S. Cl. CPC H10K 59/873; H10K 59/80524; H10K 2102/102; H10K 2102/103; H10K 2102/351

(57) ABSTRACT

A display device may include a substrate, a thin film transistor on the substrate, a display element electrically connected to the thin film transistor, and a thin film encapsulation layer on the display element, wherein the thin film encapsulation layer includes a buffer layer and a barrier layer that are sequentially stacked, and the buffer layer includes a material having a composition of SiOₓC_{y}H_{z} (wherein x>0, y>0, and z>0) and a thickness of the barrier layer is greater than a thickness of the buffer layer.

### CROSS-REFERENCE TO RELATED APPLICATION

The present application claims priority to and the benefit of Korean Patent Application No. 10-2024-0192238, filed on Dec. 20, 2024, in the Korean Intellectual Property Office, the entire disclosure of which is incorporated herein by reference.

### BACKGROUND

### 1. Field

One or more embodiments of the present disclosure relate to a display device and an electronic device including the display device.

### 2. Description of the Related Art

As demand for display devices continues to grow, there is an increasing need for display devices suitable for a variety of applications. In response to this trend, display devices are being developed to be larger and thinner, while also offering improved color accuracy and vividness. Accordingly, there is a need or desire for display devices that meet these evolving performance and design requirements.

### SUMMARY

One or more embodiments of the present disclosure are directed toward a display device having an improved or enhanced light-emitting efficiency and an electronic device including the display device.

Additional aspects of embodiments will be set forth in part in the description which follows and, in part, will be apparent from the description or may be learned by practice of the presented embodiments of the disclosure.

According to one or more embodiments of the present disclosure, a display device includes a substrate, a thin film transistor on the substrate, a display element electrically connected to the thin film transistor, and a thin film encapsulation layer on the display element, wherein the thin film encapsulation layer includes a buffer layer and a barrier layer that are sequentially stacked, and the buffer layer includes a material having a composition of SiOₓC_{y}H_{z} (wherein x>0, y>0, and z>0) and a thickness of the barrier layer is greater than a thickness of the buffer layer.

In one or more embodiments, the thickness of the buffer layer may be about 2000 Å to about 5000 Å and the thickness of the barrier layer may be about 6000 Å to about 1.5 μm.

In one or more embodiments, the barrier layer may be a single layer including at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride (e.g., SiOₓN_{y}, wherein 0<x≤2 and 0≤y≤2; e.g., SiON or Si₂N₂O).

In one or more embodiments, the buffer layer may include a first layer, a second layer, and a third layer that are sequentially stacked, and each of the first layer and the third layer may have less content (e.g., amount) of carbon (e.g., carbon (C) element) than the second layer.

In one or more embodiments, the sum of a thickness of the first layer and a thickness of the third layer may be less than a thickness of the second layer.

In one or more embodiments, the sum of the thickness of the first layer and the thickness of the third layer may be about 30% or less of the thickness of the buffer layer.

In one or more embodiments, the display element may include a first electrode, a second electrode opposite to (e.g., facing) the first electrode, and an intermediate layer including an emission layer between the first electrode and the second electrode, and the second electrode may include a single layer of a transmissive electrode including at least one selected from among indium zinc oxide (IZO), indium tin oxide (ITO), and indium gallium zinc oxide (IGZO).

In one or more embodiments, the second electrode may have a thickness of about 800 Å to about 1200 Å.

In one or more embodiments, the display device may further include a protective layer between the display element and the buffer layer, wherein the protective layer may include at least one selected from among N,N′-bis(naphthalen-1-yl)-N,N′-bis(phenyl)-2,2′-dimethylbenzidine (α-NPD), N,N′-di(1-naphthyl)-N,N′-diphenyl-(1,1′-biphenyl)-4,4′-diamine (NPB), N,N′-bis(3-methylphenyl)-N,N′-diphenylbenzidine (TPD), 4,4′,4″-tris[phenyl(m-tolyl)amino]triphenylamine (m-MTDATA), tris(8-hydroxyquinolinato)aluminum (Alq₃), and copper(II) phthalocyanine (CuPc).

In one or more embodiments, the thin film encapsulation layer may further include an organic encapsulation layer and an inorganic encapsulation layer, each being on the barrier layer, and the inorganic encapsulation layer may contact an upper surface of the barrier layer on an outside of the organic encapsulation layer.

According to one or more embodiments of the present disclosure, a display device includes a substrate, a thin film transistor on the substrate, a display element electrically connected to the thin film transistor, and a thin film encapsulation layer on the display element, wherein the thin film encapsulation layer includes a buffer layer and a barrier layer that are sequentially stacked, the buffer layer includes a material having a composition of SiOₓC_{y}H_{z} (wherein x>0, y>0, and z>0), and the buffer layer includes a first layer, a second layer, and a third layer that are sequentially stacked, and the second layer has a greater content (e.g., amount) of carbon (e.g., carbon (C) element) than each of the first layer and the third layer.

In one or more embodiments, a composition of the buffer layer may be discontinuously changed at a boundary between the first layer and the second layer and a boundary between the second layer and the third layer.

In one or more embodiments, the sum of a thickness of the first layer and a thickness of the third layer may be less than a thickness of the second layer.

In one or more embodiments, the sum of the thickness of the first layer and the thickness of the third layer may be about 30% or less of the thickness of the buffer layer.

In one or more embodiments, the thickness of the buffer layer may be about 2000 Å to about 5000 Å and the thickness of the barrier layer may be about 6000 Å to about 1.5 μm.

In one or more embodiments, the barrier layer may be a single layer including at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride (e.g., SiOₓN_{y}, wherein 0<x≤2 and 0≤y≤2; e.g., SiON or Si₂N₂O).

In one or more embodiments, the display element may include a first electrode, a second electrode opposite to (e.g., facing) the first electrode, and an intermediate layer including an emission layer between the first electrode and the second electrode, and the second electrode may include a transmissive electrode single layer including at least one selected from among indium zinc oxide (IZO), indium tin oxide (ITO), and indium gallium zinc oxide (IGZO).

In one or more embodiments, the second electrode may have a thickness of about 800 Å to about 1200 Å.

In one or more embodiments, the display device may further include a protective layer between the display element and the buffer layer, wherein the protective layer may include at least one selected from among α-NPD, NPB, TPD, m-MTDATA, Alq₃, and CuPc.

According to one or more embodiments of the present disclosure, an electronic device includes a controller configured to generate a scan input signal, a power module configured to generate a scan input voltage, and a display device configured to display images, wherein the display device includes a substrate, a thin film transistor on the substrate, a display element electrically connected to the thin film transistor, and a thin film encapsulation layer on the display element, the thin film encapsulation layer includes a buffer layer and a barrier layer that are sequentially stacked, and the buffer layer includes a material having a composition of SiOₓC_{y}H_{z} (wherein x>0, y>0, and z>0) and a thickness of the barrier layer is greater than a thickness of the buffer layer.

For example, in accordance with one or more embodiments of the present disclosure, the improvement or enhancement in light-emitting efficiency and device reliability may be attributed to the structural design and material composition of the thin film encapsulation layer. The encapsulation layer may include a buffer layer and a barrier layer that are sequentially stacked to form or provide a multilayered protective structure over the display element. The buffer layer may include a composition of SiOₓC_{y}H_{z} (where x>0, y>0, and z>0) and may be configured or provided with a three-layer architecture in which a carbon-rich intermediate layer is between two carbon-lean outer layers. This configuration may enhance mechanical flexibility and interfacial adhesion while reducing the likelihood of defect formation during deposition or subsequent processing steps.

The barrier layer, which is thicker than the buffer layer, may be formed from or composed of one or more high-performance inorganic materials, such as silicon nitride, aluminum oxide, and/or silicon oxynitride. These materials exhibit excellent or suitable barrier properties against environmental contaminants, such as moisture and/or oxygen. The synergistic combination of the buffer and barrier layers provides robust encapsulation that not only protects the underlying display elements but also enables the fabrication of thinner, lighter, and more color-accurate display panels. As a result, the disclosed structure supports the development of next-generation electronic devices with enhanced visual performance and extended operational lifespans.

### BRIEF DESCRIPTION OF THE DRAWINGS

The above and other aspects and features of certain embodiments of the present disclosure will be more apparent from the following description taken in conjunction with the accompanying drawings in which:

FIG. 1 is a plan view schematically illustrating an example of a display device according to one or more embodiments;

FIG. 2 is a cross-sectional view schematically illustrating an example of a cross-section taken along the line I-I′ of FIG. 1;

FIG. 3 is a circuit diagram illustrating an example of an equivalent circuit in one (sub-)pixel of the display device of FIG. 1;

FIG. 4 is a cross-sectional view schematically illustrating an example of part A of FIG. 2;

FIG. 5 is a cross-sectional view illustrating a buffer layer around (e.g., surrounding) a particle of FIG. 2;

FIG. 6 is a cross-sectional view schematically illustrating another example of a cross-section taken along the line I-I′ of FIG. 1;

FIG. 7 is a cross-sectional view schematically illustrating another example of a cross-section taken along the line I-I′ of FIG. 1;

FIG. 8 is a cross-sectional view schematically illustrating another example of a cross-section taken along the line I-I′ of FIG. 1;

FIG. 9 is a block diagram schematically illustrating an example of an electronic device according to one or more embodiments of the present disclosure;

FIG. 10 is a perspective view schematically illustrating an example of an electronic device including a display device according to one or more embodiments of the present disclosure;

FIG. 11 is a perspective view schematically illustrating another example of an electronic device including a display device according to one or more embodiments of the present disclosure; and

FIG. 12 is a perspective view schematically illustrating another example of an electronic device including a display device according to one or more embodiments of the present disclosure.

### DETAILED DESCRIPTION

The subject matter of the present disclosure may have one or more suitable modifications and embodiments, and thus certain embodiments will be shown in the drawings and described in more detail in the detailed description. The aspects and features of embodiments of the present disclosure and how to accomplish them will be apparent with reference to the following detailed description together with the accompanying drawings. However, the present disclosure is not limited to the embodiments as disclosed herein, but may be implemented in one or more suitable forms.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the term “and/or” includes any and all combinations of one or more of the associated listed items. For example, “A and/or B” indicates cases where it is A, or B, or both (e.g., simultaneously) A and B.

Throughout the present disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

While such terms as “first,” “second,” and/or the like may be used to describe one or more suitable components, such components are not be limited to the above terms. The above terms are used only to distinguish one component from another. For example, without departing from the scope of the present disclosure, a first element, a first component, a first region, a first layer, or a first portion may be referred to as a second element, a second component, a second region, a second layer, or a second portion, and similarly, the second element, the second component, the second region, the second layer, or the second portion may be referred to as the first element, the first component, the first region, the first layer, or the first portion.

An expression used in the singular encompasses the expression of the plural unless it has a clearly different meaning in the context.

In the present disclosure, it is to be understood that the terms “includes,” “has,” “including,” and “having” are intended to indicate the existence of the features, numbers, steps, actions, components, parts, or combinations thereof disclosed in the specification and are not intended to preclude the possibility that one or more other features, numbers, steps, actions, components, parts, or combinations thereof may exist or may be added. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be understood that if (e.g., when) a unit, a region, or a component is referred to as being “on” another unit, region, or component, it may be directly or indirectly on the other unit, region, or component. For example, intervening units, regions, or components may be present therebetween. In contrast, if (e.g., when) a unit, a region, or a component is referred to as being “directly on” another unit, region, or component, there are no intervening units, regions, or components present therebetween.

It will be understood that if (e.g., when) an element is referred to as being “connected” or “coupled” to another element, it may be directly connected or coupled to the other element or intervening elements may be present therebetween. In contrast, if (e.g., when) an element is referred to as being “directly connected” or “directly coupled” to another element, there are no intervening elements present therebetween.

If (e.g., when) a portion, such as a unit, a region, or a component, is referred to as being above or on another portion, the portion may be directly above or on the other portion or an intervening portion, such as a unit, a region, or a component, may also be present between the two portions.

The sizes of components in the drawings may be exaggerated for convenience of explanation. For example, because sizes and/or thicknesses of components in the drawings are arbitrarily illustrated for convenience of explanation, the following embodiments are not limited thereto.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

One or more embodiments of the present disclosure will be described herein in more detail with reference to the accompanying drawings. Those components that are substantially the same or are in correspondence may be rendered the same reference numeral regardless of the drawing number, and redundant explanations may not be provided.

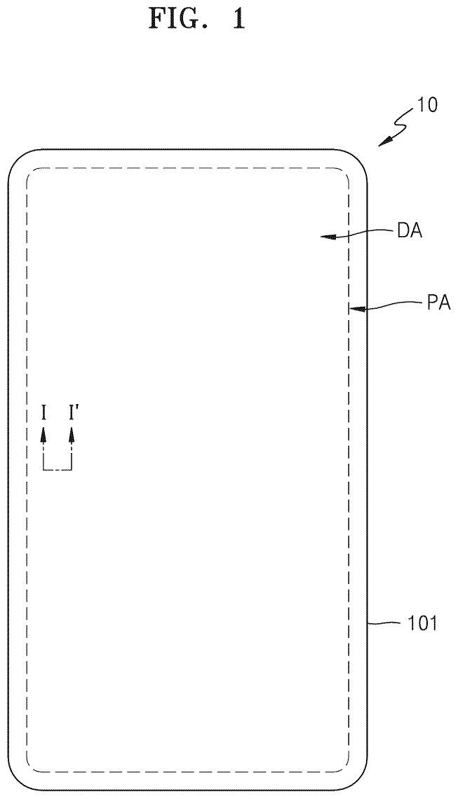

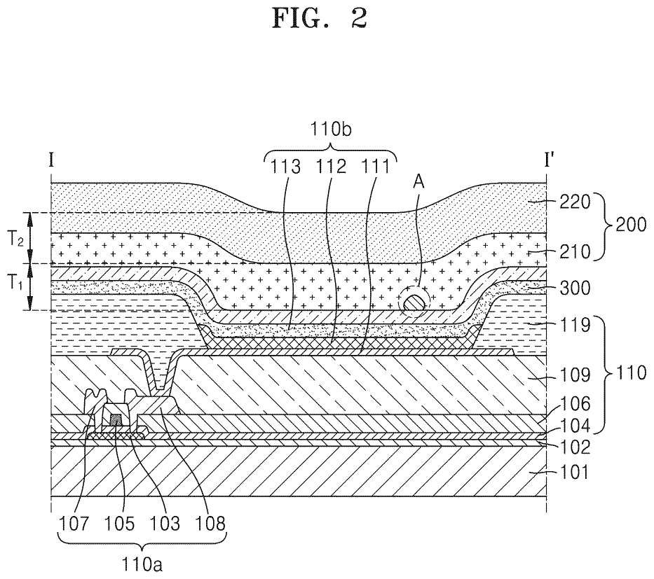

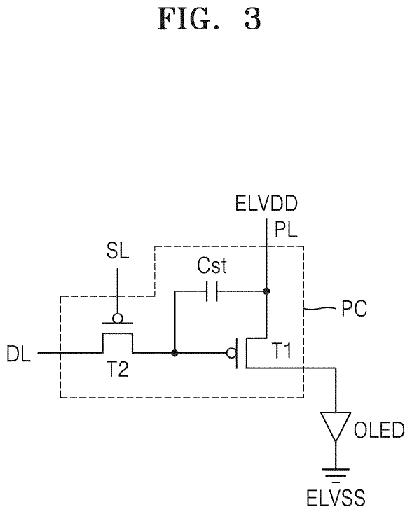

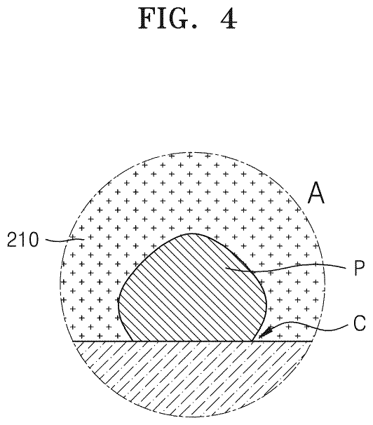

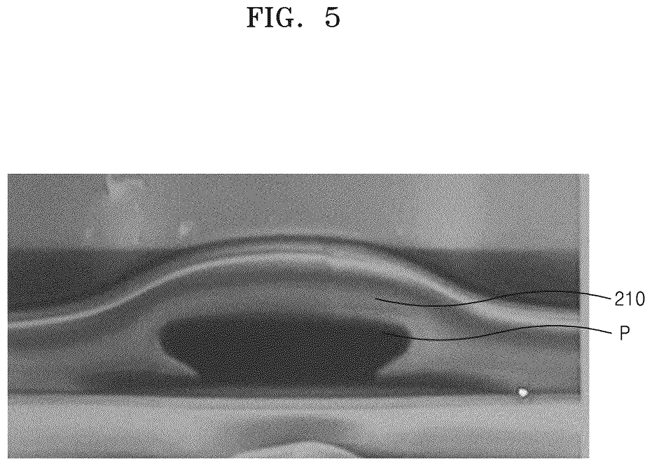

FIG. 1 is a plan view schematically illustrating an example of a display device according to one or more embodiments of the present disclosure, FIG. 2 is a cross-sectional view schematically illustrating an example of a cross-section taken along the line I-I′ of FIG. 1, FIG. 3 is a circuit diagram illustrating an example of an equivalent circuit in one (sub-)pixel of the display device of FIG. 1, FIG. 4 is a cross-sectional views schematically illustrating an example of part A in FIG. 2, and FIG. 5 is a cross-sectional view illustrating a buffer layer around (e.g., surrounding) a particle of FIG. 2.

Referring to FIG. 1 to FIG. 5, a display device 10 according to one or more embodiments of the present disclosure may include a display area DA to display images and a peripheral area PA outside the display area DA.

The display device 10 may be a device to display videos and/or still images and may be to display a screen image on a display panel and perform input/output of data. The display device 10 may be used as a display screen in mobile communication devices, such as a mobile phone, a smartphone, a tablet personal computer (PC), a mobile communication terminal, an electronic note, an electronic book, a portable multimedia player (PMP), a navigation device, an ultra-mobile PC (UMPC), and/or the like, and/or in one or more suitable electronic devices, such as a television, a laptop computer, a monitor, a billboard, an internet of things (IoT) device, and/or the like. Also, the display device 10 according to one or more embodiments of the present disclosure may be used in electronic devices, such as wearable devices, e.g., a smartwatch, a watch phone, a glasses-type (kind) display, and/or a head-mounted display (HMD). Also, the display device 10 according to one or more embodiments of the present disclosure may be used as a display of one or more suitable electric devices, e.g., a dashboard of a vehicle, a center information display (CID) on a center fascia and/or a dashboard of the vehicle, a room mirror display that replaces side-view mirrors of the vehicle, and/or a display on a rear surface of a front seat as an entertainment for backseat of the vehicle.

The display device 10, as illustrated in FIG. 2, may include a substrate 101, a display unit 110 on the substrate 101, and a thin film encapsulation layer 200 on the display unit 110. The thin film encapsulation layer 200 may include a buffer layer 210 and a barrier layer 220. The thin film encapsulation layer 200 may be to seal the display unit 110 so as to prevent external oxygen and/or moisture from infiltrating into the display unit 110 (or reduce a degree to or occurrence of which external oxygen and/or moisture infiltrate into the display unit 110).

The substrate 101 may include one or more suitable materials. For example, the substrate 101 may include a transparent (e.g., substantially transparent) glass material containing SiO₂ as a main or predominant component. However, the substrate 101 is not limited thereto, and, for example, the substrate 101 may include a transparent (e.g., substantially transparent) plastic material. The plastic material may include an insulating (e.g., electrically insulating) organic material, for example, an organic material selected from the group consisting of polyether sulfone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), cellulose acetate propionate (CAP), and/or the like.

A buffer layer 102 may be formed or arranged on the substrate 101. For example, the buffer layer 102 may include an inorganic material, such as silicon oxide, silicon nitride, silicon oxynitride, aluminum oxide, aluminum nitride, titanium oxide, titanium nitride, and/or the like, and/or an organic material, such as polyimide, polyester, acryl, and/or the like, and may have a stack structure including a plurality of materials selected from among the materials as described herein.

The display unit 110 may include a display element 110b and a thin film transistor 110a electrically connected to the display element 110b. Hereinafter, an example in which the display element 110b may include an organic emission layer, but embodiments of the present disclosure are not limited thereto, for example, the display element 110b may include one or more suitable types (kinds) of display elements, such as a light-emitting diode (LED), liquid crystal display (LCD), and/or the like.

The thin film transistor 110a may include an active layer 103, a gate electrode 105, a source electrode 107, and a drain electrode 108. Hereinafter, an example in which the thin film transistor 110a is a top-gate type (kind) in which the active layer 103, the gate electrode 105, the source electrode 107, and the drain electrode 108 are sequentially formed or arranged may be described. However, embodiments of the present disclosure are not limited thereto, and the thin film transistor 110a of one or more suitable types (kinds), such as a bottom gate type (kind) and/or the like, may be adopted.

The active layer 103 may include a semiconductor material, e.g., amorphous (e.g., non-crystalline) silicon and/or polycrystalline silicon. However, embodiments of the present disclosure are not limited to the foregoing example, and the active layer 103 may include one or more suitable materials. In one or more embodiments, the active layer 103 may include an organic semiconductor material and/or the like. In one or more embodiments, the active layer 103 may include an oxide semiconductor material. For example, the active layer 103 may include oxide of a material selected from among Group 12, 13, and/or 14 metal elements, such as zinc (Zn), indium (In), gallium (Ga), tin (Sn), cadmium (Cd), germanium (Ge), and/or the like, and/or a combination thereof.

A gate insulating layer 104 may be formed or arranged on the active layer 103. The gate insulating layer 104 may include a multi-layered structure or a single-layered structure including an inorganic material, such as silicon oxide and/or silicon nitride, and/or the like. The gate insulating layer 104 may insulate (e.g., electrically insulate) the active layer 103 and the gate electrode 105 from each other.

The gate electrode 105 may be formed or arranged on the gate insulating layer 104. The gate electrode 105 may be connected to a gate line to apply on/off signals to the thin film transistor 110a. The gate electrode 105 may include a low-resistive (e.g., electrically low-resistive) metal material. The gate electrode 105 may have, for example, a single-layered structure or a multi-layered structure including one or more materials selected from among aluminum (Al), platinum (Pt), palladium (Pd), argentum or silver (Ag), magnesium (Mg), aurum or gold (Au), nickel (Ni), neodymium (Nd), iridium (Ir), chromium (Cr), lithium (Li), calcium (Ca), molybdenum (Mo), titanium (Ti), tungsten (W), and copper (Cu).

An interlayer insulating layer 106 may be formed or arranged on the gate electrode 105. The interlayer insulating layer 106 may be to insulate (e.g., electrically insulate) the source electrode 107 and the drain electrode 108 from the gate electrode 105. The interlayer insulating layer 106 may have a single-layered structure or a multi-layered structure including an inorganic material. For example, the inorganic material may include a metal oxide and/or a metal nitride, and in more detail, the inorganic material may include silicon oxide (e.g., SiOₓ, wherein 0<x≤2; e.g., SiO₂), silicon nitride (e.g., SiNₓ, wherein 0<x≤2; e.g., Si₃N₄), silicon oxynitride (e.g., SiOₓN_{y}, wherein 0<x≤2 and 0≤y≤2; e.g., SiON or Si₂N₂O), aluminum oxide (e.g., AlOₓ, wherein 0<x≤2; e.g., Al₂O₃), titanium oxide (e.g., TiOₓ, wherein 0<x≤2; e.g., TiO₂), tantalum oxide (e.g., Ta₂O₅), hafnium oxide (e.g., HfO₂), zinc oxide (e.g., ZnOₓ, wherein 0<x≤2; e.g., ZnO₂), and/or the like.

The source electrode 107 and the drain electrode 108 may be formed or arranged on the interlayer insulating layer 106. The source electrode 107 and the drain electrode 108 may each have a single-layered structure or a multi-layered structure including one or more selected from among Al, Pt, Pd, Ag, Mg, Au, Ni, Nd, Ir, Cr, Li, Ca, Mo, Ti, W, and Cu. The source electrode 107 and the drain electrode 108 may be formed or arranged to contact the active layer 103.

A passivation layer 109 may be formed or arranged to cover the thin film transistor 110a. The passivation layer 109 may be to remove a step caused by the thin film transistor 110a and planarize the upper surface, and prevent defects from occurring in the display element 110b (or reduce a degree to or occurrence of which defects occur in the display element 110b) due to lower irregularities.

The passivation layer 109 may have a single-layered structure or a multi-layered structure including an organic material. The organic material may include a general-purpose polymer, such as polymethyl methacrylate (PMMA) and/or polystyrene (PS), polymer derivatives having phenol groups, an acryl-based polymer, an imide-based polymer, an aryl ether-based polymer, an amide-based polymer, a fluoride-based polymer, a p-xylene-based polymer, a vinyl alcohol-based polymer, and blends thereof. Also, the passivation layer 109 may have a composite stack structure including an inorganic insulating (e.g., electrically insulating) layer and/or an organic insulating (e.g., electrically insulating) layer.

The display element 110b may be formed or arranged on the passivation layer 109. The display element 110b may include a first electrode 111, a second electrode 113 opposite to (e.g., facing) the first electrode 111, and an intermediate layer 112 between the first electrode 111 and the second electrode 113.

The first electrode 111 may be electrically connected to the drain electrode 108. The first electrode 111 may have one or more suitable shapes, and, for example, may be patterned in an island shape (e.g., a substantially island shape).

The first electrode 111 may be formed or arranged on the passivation layer 109 and may be electrically connected to the thin film transistor 110a via a contact hole formed or arranged in the passivation layer 109. The first electrode 111 may be, for example, a reflective electrode. For example, the first electrode 111 may include a reflective layer including Ag, Mg, Al, Pt, Pd, Au, Ni, Nd, Ir, Cr, and a compound thereof, and a transmissive electrode layer formed or arranged on the reflective layer. The transmissive electrode layer may include at least one selected from the group consisting of indium tin oxide (ITO), indium zinc oxide (IZO), zinc oxide (e.g., ZnOₓ, wherein 0<x≤2; e.g., ZnO), indium oxide (e.g., In₂O₃), indium gallium oxide (IGO), and aluminum zinc oxide (AZO).

A pixel-defining layer 119 including an insulating (e.g., electrically insulating) material may be formed or arranged on the first electrode 111. The pixel-defining layer 119 may include one or more organic insulating (e.g., electrically insulating) materials selected from the group consisting of polyimide, polyamide, an acrylic resin, benzo cyclobutene, and a phenol resin and may be manufactured by a spin coating method and/or the like. The pixel-defining layer 119 may expose a certain (e.g., set or predetermined) region of the first electrode 111, and the intermediate layer 112 including an organic emission layer may be on the exposed region. For example, the pixel-defining layer 119 may define a pixel region of the organic light-emitting device.

The organic emission layer included in the intermediate layer 112 may include a low-molecular weight organic material and/or a high-molecular weight organic material, and the intermediate layer 112 may further include one or more functional layers, such as a hole transport layer (HTL), a hole injection layer (HIL), an electron transport layer (ETL), and/or an electron injection layer (EIL), in addition to the emission layer.

The second electrode 113 opposite to (e.g., facing) the first electrode 111 may be a transmissive electrode including at least one selected from among indium zinc oxide (IZO), indium tin oxide (ITO), and indium gallium zinc oxide (IGZO). For example, unlike the transmissive layer stacked on a thin metal film, such as Ag, Al, and/or the like, in the related art, the second electrode 113 may include a single layer of the transmissive electrode, such as IZO and/or the like. As a result, a non-resonant structure may be obtained, and the transmissive electrode layer, such as IZO and/or the like, included in the second electrode 113 may have a relatively larger thickness. For example, the second electrode 113 may have a thickness of about 800 Å to about 1200 Å and the second electrode 113 may have minimum or reduced damage due to post-processes having excellent or suitable light transmittance.

Therefore, the second electrode 113 may be to transmit the light emitted from the organic emission layer included in the intermediate layer 112. For example, the light emitted from the organic emission layer may be discharged toward the second electrode 113 directly or after being reflected by the first electrode 111 including the reflective electrode.

The thin film encapsulation layer 200 may be to seal the display unit 110 so as to prevent external oxygen and/or moisture from infiltrating into the display unit 110 (or reduce a degree to or occurrence of which external oxygen and/or moisture infiltrate into the display unit 110). The thin film encapsulation layer 200 may be implemented to be thin by including one buffer layer 210 and one barrier layer 220.

In one or more embodiments, if (e.g., when) the second electrode 113 is formed or arranged as the transmissive electrode, such as IZO, as illustrated in FIG. 4, a particle P of the IZO and/or the like may be formed or arranged on the second electrode 113 during the process of forming or arranging the second electrode 113. The particle P may cause a step with respect to the surface of the second electrode 113, and accordingly, stress may be concentrated on the particle P that generates the step if (e.g., when) the external force is applied to the display device 10, and thus, damage, such as a crack and/or the like, may occur in the thin film encapsulation layer 200 on the particles P, for example, the barrier layer 220.

Also, if (e.g., when) a contact angle between the particle P and the second electrode 113 is small, the thin film encapsulation layer 200 may not completely (e.g., substantially completely) fill in a space C between the particle P and the second electrode 113, and a gap may occur in the space C between the second electrode 113 and the thin film encapsulation layer 200.

The buffer layer 210 may be to lessen the step (or reduce a degree or occurrence of the step) generated by the particle P, so as to prevent damage (or reduce a degree or occurrence of damage) to the barrier layer 220 due to the step or the stress concentration during applying the external force, and because the buffer layer 210 is formed or arranged to be completely (e.g., substantially completely) around (or surround) the particles P, the gap may be prevented from being generated in the space C between the second electrode 113 and the particle P (or a degree to or occurrence of which the gap is generated in the space C between the second electrode 113 and the particle P may be reduced) even if (e.g., when) the contact angle between the particle P and the second electrode 113 is an acute angle.

To this end, the buffer layer 210 may include silicon oxide including carbon and hydrogen. For example, the buffer layer 210 may include a material having a formula of SiOₓC_{y}H_{z} (wherein x>0, y>0, and z>0), and if (e.g., when) a composition ratio of x increases, the buffer layer 210 may have a property similar to an inorganic layer, and if (e.g., when) a composition ratio of y increases, the buffer layer 210 may have a property similar to an organic layer. The buffer layer 210 may be formed or arranged through, for example, a chemical vapor deposition in a vacuum state by using hexamethyldisiloxane (HMDSO) as a raw material gas and oxygen and/or nitrous oxide as a reaction gas.

The buffer layer 210 as described in one or more embodiments may have excellent or suitable gap filling characteristics, and thus, the buffer layer 210 may be completely (e.g., substantially completely) around (or surround) the particle P so as to prevent the gap from being generated in the space C between the second electrode 113 and the particle P (or reduce a degree to or occurrence of which the gap is generated in the space C between the second electrode 113 and the particle P) and have an upper surface that is flat (e.g., substantially flat) or slightly curved.

In more detail, as illustrated in FIG. 5, the buffer layer 210 may be formed or arranged to be completely (e.g., substantially completely) around (or surround) the particle P, and at this time, the upper surface of the buffer layer 210 may include a curved surface that is changed from a concave shape (e.g., a substantially concave shape) to a convex shape (e.g., a substantially convex shape) from a periphery of the particle P toward the part overlapping the particle P. Herein, the concave shape denotes a shape curved toward the substrate 101 and the convex shape may denote a shape curved to opposite to the substrate 101. As described in one or more embodiments, because the step caused by the particle P is lessened (or a degree or occurrence of the step caused by the particle P is reduced) by the buffer layer 210, the damage, such as crack, to the thin film encapsulation layer 200, for example, the barrier layer 220, may be prevented (or a degree or occurrence of the damage, such as crack, to the thin film encapsulation layer 200, for example, the barrier layer 220, may be reduced).

Moreover, because the buffer layer 210 has a high transmittance that is nearly 100%, light absorption loss due to the buffer layer 210 may rarely occur if (e.g., when) the light is emitted to the outside through the second electrode 113.

The buffer layer 210 may have a thickness T₁ of about 2000 Å to about 5000 Å. If (e.g., when) the thickness T₁ of the buffer layer 210 is less than about 5000 Å, it may be difficult for the buffer layer 210 to address or avoid the step caused by the particle P, and if (e.g., when) the thickness T₁ of the buffer layer 210 is greater than about 5000 Å, a total thickness of the thin film encapsulation layer 200 may increase, and there may be unhardened part in the buffer layer 210, which may cause excessively or substantially soft property, and thus, wrinkles and/or the like may be generated in the buffer layer 210.

The barrier layer 220 may be to block infiltration of external moisture and/or oxygen and may be formed or arranged to be greater than the buffer layer 210 so as to cover an upper surface and a side surface of the buffer layer 210 and may entirely (e.g., substantially entirely) encompass the buffer layer 210.

The barrier layer 220 may include at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride (e.g., SiOₓN_{y}, wherein 0<x≤2 and 0≤y≤2; e.g., SiON or Si₂N₂O).

The barrier layer 220 may be formed or arranged by substantially the same method as the method of forming or arranging the buffer layer 210 only by utilizing different raw gas, in the chamber in which the buffer layer 210 is formed or arranged. Therefore, if (e.g., when) forming or arranging the thin film encapsulation layer 200, a tact time may be reduced.

In one or more embodiments, a thickness T₂ of the barrier layer 220 may be about 6000 Å to about 1.5 μm. For example, the thickness T₂ of the barrier layer 220 may be greater than the thickness T₁ of the buffer layer 210. If (e.g., when) the thickness T₂ of the barrier layer 220 is less than 6000 Å, infiltration of the external moisture and/or oxygen may not be effectively or suitably prevented (or a degree or occurrence of infiltration of the external moisture and/or oxygen may not be effectively or suitably reduced) due to the barrier layer 220 that is formed or arranged as a single layer on the buffer layer 210, and if (e.g., when) the thickness T₂ of the barrier layer 220 is greater than about 1.5 μm, a strength of the barrier layer 220 may excessively or substantially increase, and accordingly, damage to the barrier layer 220 may occur due to the external impact and the flexible characteristic of the display device 10 may not be sufficiently or suitably implemented.

FIG. 3 is an equivalent circuit diagram schematically illustrating a pixel circuit PC that may be applied to the display panel.

Referring to FIG. 3, the pixel circuit PC may be connected to a display element, e.g., an organic light-emitting diode OLED. The pixel circuit PC may include a driving thin film transistor T1, a switching thin film transistor T2, and a storage capacitor Cst. The organic light-emitting diode OLED may be to emit red light, green light, or blue light or may be to emit red light, green light, blue light, or white light.

The switching thin film transistor T2 may be connected to a scan line SL and a data line DL and may be configured to transfer a scan signal input from the scan line SL or a data signal or a data voltage input from the data line DL based on a switching voltage to the driving thin film transistor T1. The storage capacitor Cst may be connected to the switching thin film transistor T2 and a driving voltage line PL and may be to store a voltage corresponding to a difference between a voltage transferred from the switching thin film transistor T2 and a first power voltage ELVDD supplied to the driving voltage line PL.

The driving thin film transistor T1 may be connected to the driving voltage line PL and the storage capacitor Cst and may be to control a driving current that flows from the driving voltage line PL to the organic light-emitting diode OLED in response to the voltage value stored in the storage capacitor Cst. The organic light-emitting diode OLED may be to emit light having a certain (e.g., set or predetermined) luminance according to the driving current. A second electrode 113 of the organic light-emitting diode OLED may be to receive supply of a second power voltage ELVSS.

FIG. 3 illustrates that the pixel circuit PC includes two thin film transistors and one storage capacitor, but the pixel circuit PC may include three, four, five, or more thin film transistors.

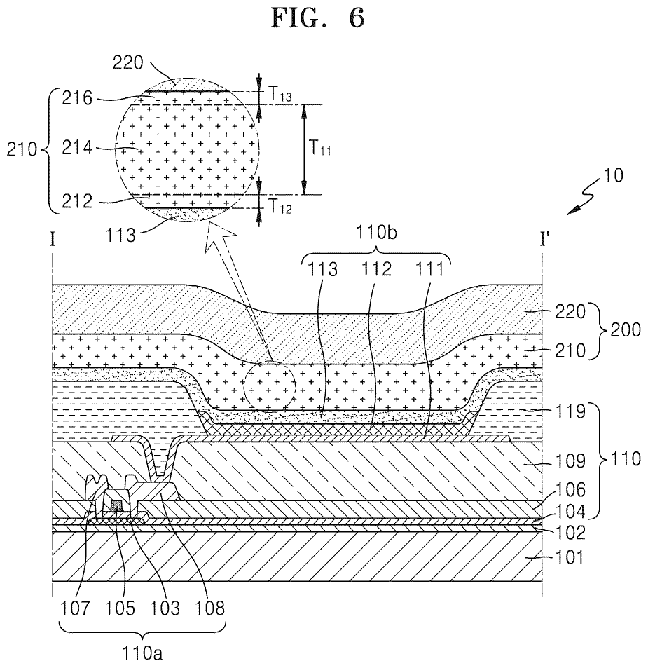

FIGS. 6 to 8 are cross-sectional views schematically illustrating examples of the cross-section taken along the line I-I′ of FIG. 1.

First, referring to FIG. 6, the display device 10 may include the substrate 101, the display unit 110 on the substrate 101, and the thin film encapsulation layer 200 on the display unit 110. The display unit 110 may include the thin film transistor 110a and the display element 110b. In one or more embodiments, the thin film encapsulation layer 200 may be to seal the display unit 110 so as to prevent external oxygen and/or moisture from infiltrating into the display unit 110 (or reduce a degree to or occurrence of which external oxygen and/or moisture infiltrate into the display unit 110) and may include the buffer layer 210 and the barrier layer 220.

The buffer layer 210 may include silicon oxide including carbon and hydrogen. For example, if (e.g., when) hexamethyldisiloxane (HMDSO) is used as a raw gas and oxygen is used as a reaction gas, hexamethyldisiloxane may be decomposed into monomer units, and then, the buffer layer 210 having a composition of SiOₓC_{y}H_{z} (wherein x>0, y>0, z>0) may be formed.

In one or more embodiments, if (e.g., when) decomposing hexamethyldisiloxane, carbonate groups and methyl groups may be formed, and at this time, as a flow rate of the oxygen that is the reaction gas may increase, an oxidation reaction may become dominant, and a carbon content (e.g., amount) in the deposited buffer layer 210 may be reduced. If (e.g., when) the carbon content (e.g., amount) in the buffer layer 210 is reduced, the buffer layer 210 may have properties close to properties of the inorganic layer, and thus, the characteristics of the buffer layer 210 may be adjusted by adjusting the flow rate of the oxygen and/or replacing the oxygen with nitrous oxide if (e.g., when) forming or arranging the buffer layer 210.

Referring to FIG. 6, the buffer layer 210 may include a first layer 212, a second layer 214, and a third layer 216 that are sequentially stacked. The first layer 212 and the third layer 216 may have higher oxygen content (e.g., amount) and less carbon content (e.g., amount) as compared with the second layer 214 and include hydrogen-bonded silicon carbide so as to have stronger characteristics of the inorganic layer. The second layer 214 may have stronger characteristics of organic layer as compared with the first layer 212 and the third layer 216.

For example, the first layer 212 and the third layer 216 may each include about 30 atomic % to about 40 atomic % of silicon, about 20 atomic % to about 30 atomic % of oxygen, and about 30 atomic % to about 40 atomic % of carbon based on the total sum of the number of atoms in silicon, oxygen, and carbon, and the second layer 214 may include about 20 atomic % to about 40 atomic % of silicon, about 10 atomic % to about 25 atomic % of oxygen, and about 40 atomic % to about 50 atomic % of carbon based on the total sum of the number of atoms in silicon, oxygen, and carbon.

Because the first layer 212 has relatively stronger characteristics of the inorganic layer as compared with the second layer 214, the bonding force with the second electrode 113 may be improved or enhanced, and during the process of forming or arranging the first layer 212 and/or the like, an outgassing effect may be reduced and damage to the display element 110b due to the discharged gas may be prevented (or a degree or occurrence of damage to the display element 110b due to the discharged gas may be reduced).

Likewise, the third layer 216 may have stronger characteristics of inorganic layer as compared with the second layer 214, a bonding force with the barrier layer 220 formed or arranged on the second electrode 113 may be improved or enhanced.

Because the second layer 214 has stronger characteristics of organic layer as compared with the first layer 212 and the third layer 216, the step caused by the particle and/or the like on the second electrode 113 may be reduced and planarized.

In one or more embodiments, the sum of a thickness T₁₂ of the first layer 212 and a thickness T₁₃ of the third layer 216 may be less than a thickness T₁₁ of the second layer 214. For example, in consideration of the bonding force between the second electrode 113 and the barrier layer 220 and the coverage of the particle, the sum of the thickness T₁₂ of the first layer 212 and the thickness T₁₃ of the third layer 216 may be about 30% or less of the total thickness of the buffer layer 210, and the thickness T₁₁ of the second layer 214 may be about 70% or greater of the total thickness of the buffer layer 210.

The composition of each of the first layer 212, the second layer 214, and the third layer 216 may be changed discontinuously at the boundaries among the first layer 212, the second layer 214, and the third layer 216. For example, the first layer 212 may be formed or arranged by depositing HDMSO via a chemical vapor deposition method and hardening the deposited HDMSO, and the second layer 214 may be formed or arranged by substantially the same method as the method of forming or arranging the first layer 212. However, the second layer 214 may be formed or arranged to have different composition from the first layer by adjusting a flow rate of the reaction gas, such as oxygen. Therefore, the composition of the buffer layer 210 may be discontinuously changed at the boundary between the first layer 212 and the second layer 214, and the boundary between the first layer 212 and the second layer 214 may be partitioned and displayed. Likewise, the composition of the buffer layer 210 may be discontinuously changed at the boundary between the second layer 214 and the third layer 216, and the boundary between the second layer 214 and the third layer 216 may be partitioned and displayed.

Also, a refractive index may gradually increase toward the first layer 212, the second layer 214, and the third layer 216. For example, if (e.g., when) the first layer 212 includes more fluorine (F) than the second layer 214, the refractive index of the first layer 212 may be low. If (e.g., when) the refractive index is gradually increased in the direction of the first layer 212, the second layer 214, and the third layer 216, the light generated from the display element 110b may be prevented from being extinguished during the process of being emitted to outside (or a degree to or occurrence of which the light generated from the display element 110b is extinguished during the process of being emitted to outside may be reduced), and a light-extraction efficiency of the display device 10 may be improved or enhanced.

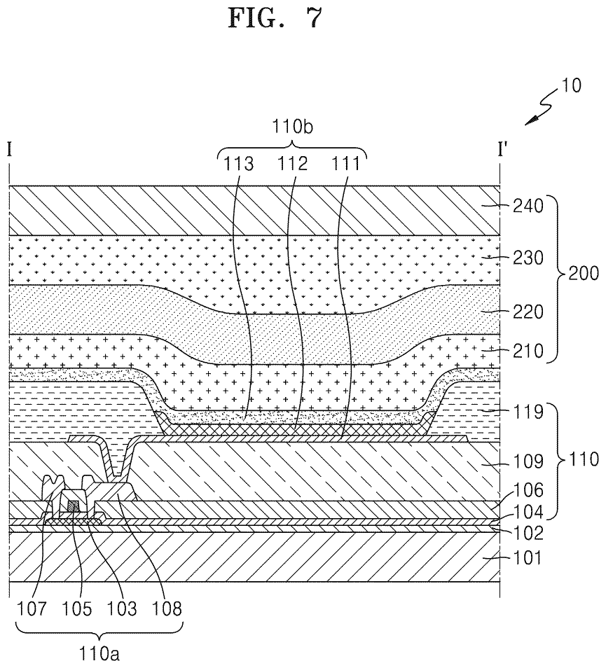

Next, referring to FIG. 7, the display device 10 may include the substrate 101, the display unit 110 on the substrate 101, and the thin film encapsulation layer 200 on the display unit 110. The display unit 110 may include the thin film transistor 110a and the display element 110b. Also, the thin film encapsulation layer 200 may be to seal the display unit 110 so as to prevent external oxygen and/or moisture from infiltrating into the display unit 110 (or reduce a degree to or occurrence of which external oxygen and/or moisture infiltrate into the display unit 110). In one or more embodiments, FIG. 7 illustrates an example in which the thin film encapsulation layer 200 further includes an organic encapsulation layer 230 and an inorganic encapsulation layer 240 on the barrier layer 220.

The organic encapsulation layer 230 may be formed or arranged on the barrier layer 220 and may planarize curvature that remains in the barrier layer 220, and may reduce the stress to the barrier layer 220 and the inorganic encapsulation layer 240 so as to prevent the cracks from occurring in the barrier layer 220 and the inorganic encapsulation layer 240 (or reduce a degree to or occurrence of which the cracks occur in the barrier layer 220 and the inorganic encapsulation layer 240).

The organic encapsulation layer 230 may include a polymer-based material. The polymer-based material may include an acryl-based resin, an epoxy-based resin, polyimide, polyethylene, and/or the like. In one or more embodiments, the organic encapsulation layer 230 may include acrylate.

The inorganic encapsulation layer 240 may include a material that is substantially the same as the material included in the barrier layer 220 so as to prevent external moisture and/or oxygen from infiltrating toward the display element 110b (or reduce a degree to or occurrence of which external moisture and/or oxygen infiltrate toward the display element 110b). For example, the inorganic encapsulation layer 240 may include one or more inorganic materials selected from among aluminum oxide, titanium oxide, tantalum oxide, hafnium oxide, zinc oxide, silicon oxide, silicon nitride, and silicon oxynitride.

In one or more embodiments, the barrier layer 220 and the inorganic encapsulation layer 240 may have greater areas than the organic encapsulation layer 230, and the inorganic encapsulation layer 240 may contact the upper surface of the barrier layer 220 on the outside of the organic encapsulation layer 230. For example, the organic encapsulation layer 230 may be capsulized by the barrier layer 220 and the inorganic encapsulation layer 240.

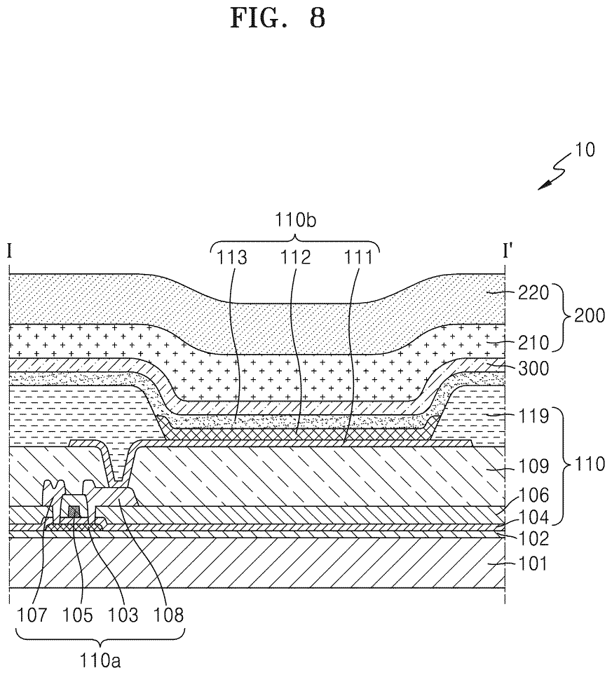

Next, referring to FIG. 8, the display device 10 may include the substrate 101 and the display unit 110 on the substrate 101, and the display unit 110 may include the thin film transistor 110a and the display element 110b. In one or more embodiments, the thin film encapsulation layer 200 may be to seal the display unit 110 so as to prevent external oxygen and/or moisture from infiltrating into the display unit 110 (or reduce a degree to or occurrence of which external oxygen and/or moisture infiltrate into the display unit 110) and may include the buffer layer 210 and the barrier layer 220.

Because the display unit 110 and the thin film encapsulation layer 200 may each independently be substantially the same as those described in one or more embodiments with reference to FIGS. 1 to 7, redundant descriptions may not be provided.

Referring to FIG. 8, the display device 10 may further include a protective layer 300 on the display unit 110. For example, the protective layer 300 may be formed or arranged between the second electrode 113 and the buffer layer 210.

The protective layer 300 may be formed or arranged on the second electrode 113 to protect the display element 110b and may be to assist the light generated from the display element 110b to be effectively or suitably emitted. For example, the protective layer 300 may include at least one selected from among α-NPD, NPB, TPD, m-MTDATA, Alq₃, and CuPc. Herein, a refractive index of the protective layer 300 may range from about 1.6 to about 3.0. However, embodiments of the present disclosure are not limited thereto, and the protective layer 300 may be formed or composed of a material capable of shielding the moisture and/or oxygen.

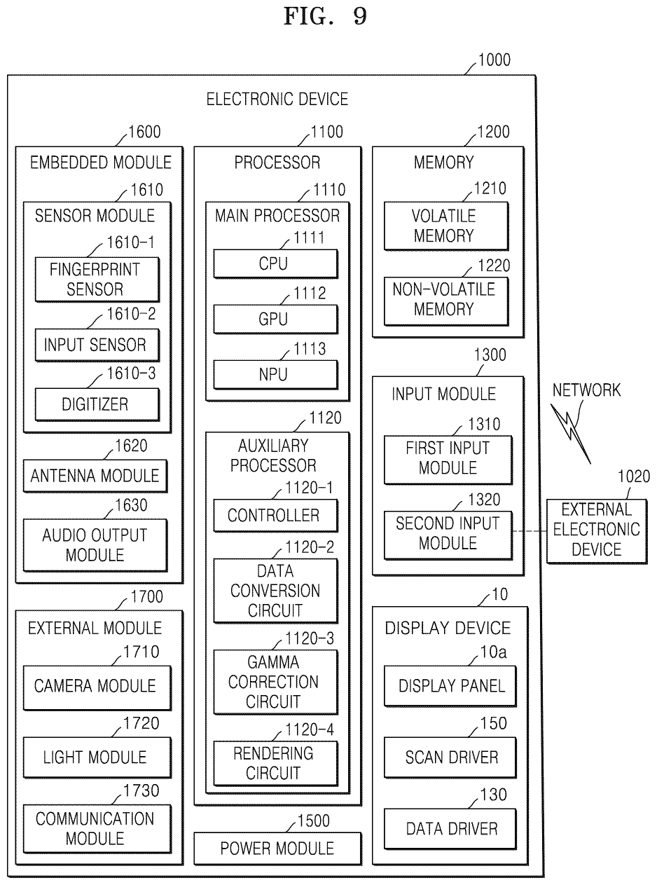

FIG. 9 is a block diagram schematically illustrating an example of an electronic device according to one or more embodiments of the present disclosure.

Referring to FIG. 9, the electronic device 1000 may be to output one or more suitable information through the display device 10 in an operating system. Herein, the display device 10 may be the display device as illustrated and described in more detail with reference to FIG. 1. If (e.g., when) a processor 1100 executes an application stored in a memory 1200, the display device 10 may provide a user with application information through a display panel 10a.

The processor 1100 may be to obtain an external input through an input module 1300 or a sensor module 1610 and execute an application corresponding to the external input. For example, if (e.g., when) the user selects a camera icon displayed on the display panel 10a, the processor 1100 may obtain a user input through an input sensor 1610-2 and activate a camera module 1710. The processor 1100 may be to transfer image data corresponding to a captured image obtained through the camera module 1710 to the display device 10. The display device 10 may be to display an image corresponding to the captured image through the display panel 10a.

In another example, if (e.g., when) personal information verification is carried out in the display device 10, a fingerprint sensor 1610-1 may obtain input fingerprint information as input data. The processor 1100 may be to compare the input data obtained through the fingerprint sensor 1610-1 with verification data stored in the memory 1200 and execute an application according to a comparison result. The display device 10 may be to display, on the display panel 10a, information executed according to a logic of the application.

In another example, if (e.g., when) a music streaming icon displayed on the display device 10 is selected, the processor 1100 may obtain the user input through the input sensor 1610-2 and activate a music streaming application stored in the memory 1200. If (e.g., when) a music execution command is input from the music streaming application, the processor 1100 may activate a sound output module 1630 to provide the user with sound information matching with the music execution command.

Operations of the electronic device 1000 are described herein briefly. Hereinafter, components of the electronic device 1000 are described in more detail. One or more of the components of the electronic device 1000 as described herein may be integrated and provided as one component, and one component may be divided into two or more components and provided.

Referring to FIG. 9, the electronic device 1000 may be to communicate with an external electronic device 1020 via a network (e.g., a short-range wireless communication network and/or a long-distance wireless communication network). According to one or more embodiments, the electronic device 1000 may include the processor 1100, the memory 1200, the input module 1300, the display device 10, a power module 1500, a built-in module 1600, and an external module 1700. According to one or more embodiments, in the electronic device 1000, at least one selected from among the foregoing components may not be provided or one or more other components may be added. According to one or more embodiments, one or more (e.g., the sensor module 1610, an antenna module 1620, or the sound output module 1630) selected from among the foregoing components may be integrated with one another component (e.g., the display device 10).

The processor 1100 may be to execute software to control at least one another component of the electronic device 1000 connected to the processor 1100 (e.g., a hardware component and/or a software component) and perform one or more suitable data processing or operations. According to one or more embodiments, as at least one or more of the data processing or operations, the processor 1100 may be to store commands or data transmitted from another component (e.g., the input module 1300, the sensor module 1610, or a communication module 1730) in a volatile memory 1210, process commands or data stored in the volatile memory 1210, and store result data in a non-volatile memory 1220.

The processor 1100 may include a main processor 1110 and an auxiliary processor 1120. The main processor 1110 may include at least one of a central processing unit (CPU) 111-1 or an application processor (AP). The main processor 1110 may further include at least one selected from among a graphic processing unit (GPU) 1110-2, a communication processor (CP), and an image signal processor (ISP). The main processor 1110 may further include a neural processing unit (NPU) 1110-3. The NPU may be a processor specialized in processing of an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of at least two thereof, but embodiments of the present disclosure are not limited to the examples as described herein. The artificial intelligence model may additionally or alternatively include a software structure in addition to a hardware structure. At least two selected from among the processing units and the processors as described herein may be implemented as one integrated component (e.g., a single chip) or may be implemented as independent components (e.g., a plurality of chips), respectively.

The auxiliary processor 1120 may include a controller 1120-1. The controller 1120-1 may include an interface conversion circuit and a timing control circuit. The controller 1120-1 may be to receive an image signal from the main processor 1110 and output image data by converting a data format of the image signal to be suitable for specification of an interface with the display device 10. The controller 1120-1 may be to output one or more suitable control signals to drive the display device 10.

The auxiliary processor 1120 may further include the controller 1120-1, a data conversion circuit 1120-2, a gamma correction circuit 1120-3, a rendering circuit 1120-4, and/or the like. The data conversion circuit 1120-2 may be to receive the image data from the controller 1120-1 and may be to compensate for the image data so that the image may be displayed with a desired or suitable luminance according to the characteristics of the electronic device 1000 or setting of the user or may be to convert the image data to reduce power consumption or compensate for an afterimage. The gamma correction circuit 1120-3 may be to convert the image data or a gamma reference voltage such that the image displayed on the electronic device 1000 has desired or suitable gamma characteristics. The rendering circuit 1120-4 may be to receive the image data from the controller 1120-1 and may be to render the image data in consideration of pixel arrangement and/or the like of the display panel 10a applied to the electronic device 1000. At least one selected from among the data conversion circuit 1120-2, the gamma correction circuit 1120-3, and the rendering circuit 1120-4 may be integrated with another component (e.g., main processor 1110 or controller 1120-1). At least one selected from among the data conversion circuit 1120-2, the gamma correction circuit 1120-3, and the rendering circuit 1120-4 may be integrated with a data driver 130 that is described herein.

The memory 1200 may be to store one or more suitable data used by at least one components (e.g., processor 1100 or sensor module 1610) of the electronic device 1000 and input data or output data regarding commands related to the data. The memory 1200 may include at least one selected from the volatile memory 1210 and the non-volatile memory 1220.

The input module 1300 may be to receive commands or data used in the components (e.g., the processor 1100, the sensor module 1610, or the music output module 1630) of the electronic device 1000 from the outside of the electronic device 1000 (e.g., user or external electronic device 1020).

The input module 1300 may include a first input module 1310 to which commands or data is input from the user and a second input module 1320 to which commands or data is input from the external electronic device 1020. The first input module 1310 may include a microphone, a mouse, a keyboard, a key (e.g., a button) and/or a pen (e.g., a passive pen and/or an active pen). The second input module 1320 may be to support a designated protocol capable of connecting to the external electronic device 1020 by wire and/or wirelessly. According to one or more embodiments, the second input module 1320 may include a high-definition multimedia interface (HDMI), a universal serial bus (USB) interface, a secure digital (SD) card interface, and/or an audio interface. The second input module 1320 may include a connector physically connected to the external electronic device 1020, for example, an HDMI connector, a USB connector, an SD card connector, and/or an audio connector (e.g., a headphone connector).

The display device 10 may be to display images and provide the user with information visually. The display device 10 may include the display panel 10a, a scan driver 150, and a data driver 130. The display device 10 may further include a window, a chassis, and/or a bracket to protect the display panel 10a.

The display panel 10a may further include a light-emission driver. The light-emission driver may be to output a light emission control signal to the display panel 10a in response to a control signal received from the controller 1120-1. The light emission driver may be formed or arranged independently from the scan driver 150 or integrated with the scan driver 150.

The scan driver 150 may be to receive a control signal from the controller 1120-1 and output scan signals to the display panel 10a in response to the control signal. For example, the control signal generated by the controller 1120-1 and transferred to the scan driver 150 may be a scan input signal to control the scan driver 150. The scan input signal may be an input signal applied to switching elements included in stages of the scan driver.

The data driver 130 may be to receive the control signal from the controller 1120-1 and convert the image data into an analog voltage (e.g., data voltage) in response to the control signal and output the data voltages to the display panel 10a. For example, the control signal generated by the controller 1120-1 and transferred to the data driver 130 may be an input signal to control the data driver 130.

The data driver 130 may be integrated with another component (e.g., controller 1120-1). Functions of the interface conversion circuit and the timing control circuit of the controller 1120-1 may be integrated with the data driver 130.

The controller 1120-1 may be to generate a clock signal that is necessary or desired to drive the scan driver 150. Each of the stages in the scan driver 150 may be to operate based on the clock signal corresponding to each stage.

The scan driver 150 may be to generate the scan signal based on a scan input signal, a clock signal, and a scan input voltage. The scan signal may be transferred to the pixel circuit, and the thin film transistor included in the pixel circuit may be driven based on the scan signal. The scan signal may be transferred to a gate included in the pixel circuit.

The display device 10 may further include a light-emission driver, a voltage generation circuit, and/or the like. The voltage generation circuit may be to output one or more suitable voltages that are necessary or desired to drive the display panel 10a.

The power module 1500 may be to supply electric power to the components of the electronic device 1000. The power module 1500 may be to generate a gate driving voltage (e.g., gate high voltage and/or gate low voltage) necessary or desired to drive the scan driver 150.

For example, the power module 1500 may denote a power generator, a power supply, and/or the like. For example, the power module 1500 may include a battery charging power voltage. The battery may include a primary battery that is not rechargeable, a secondary battery that is rechargeable, or a fuel cell.

For example, the power module 1500 may include a power management integrated circuit (PMIC). The PMIC may be to supply power improved or optimized for each of the modules as described in one or more embodiments and modules that are to be described herein.

For example, the power module 1500 may include a wireless power transmitting/receiving member that is electrically connected to the battery. The wireless power transmitting/receiving member may include a plurality of antenna radiators having coil shapes.

The electronic device 1000 may further include the built-in module 1600 and the external module 1700. The built-in module 1600 may include the sensor module 1610, the antenna module 1620, and the sound output module 1630. The external module 1700 may include the camera module 1710, a light module 1720, and the communication module 1730.

The sensor module 1610 may be to sense an input from the body part of the user and/or a pen input onto the first input module 1310 and generate an electrical signal or data value corresponding to the input. The sensor module 1610 may include at least one selected from among the fingerprint sensor 1610-1, the input sensor 1610-2, and a digitizer 1610-3.

The fingerprint sensor 1610-1 may be to generate a data value corresponding to the fingerprint of the user. The fingerprint sensor 1610-1 may include one selected from a fingerprint sensor of an optical type (kind) and a fingerprint sensor of a capacitive type (kind).

The input sensor 1610-2 may be to generate a data value corresponding to coordinate information of the input from the body part of the user and/or a pen input. The input sensor 1610-2 may be to generate a variation amount in capacitance due to the input as a data value. The input sensor 1610-2 may be to sense an input from a passive pen or transmit/receive data to/from an active pen.

The input sensor 1610-2 may be to measure a biological signal, such as blood pressure, moisture, and/or body fat. For example, if (e.g., when) the user does not move for a certain (e.g., set or predetermined) period of time after touching a sensor layer or a sensing panel by the body part, the input sensor 1610-2 may sense the biological signal and output information desired or suitable by the user to the display device 10 based on a change in an electric field due to the body part.

The digitizer 1610-3 may be to generate a data value corresponding to coordinate information of the pen input. The digitizer 1610-3 may be to generate an electromagnetic variation amount due to the input as the data value. The digitizer 1610-3 may be to sense an input from a passive pen or transmit/receive data to/from an active pen.

At least one selected from among the fingerprint sensor 1610-1, the input sensor 1610-2, and the digitizer 1610-3 may be implemented as a sensor layer formed or arranged on the display panel 10a through consecutive processes. The fingerprint sensor 1610-1, the input sensor 1610-2, and the digitizer 1610-3 may be arranged on the upper side of the display panel 10a, and one selected from among the fingerprint sensor 1610-1, the input sensor 1610-2, and the digitizer 1610-3, e.g., digitizer 1610-3, may be arranged on the lower side of the display panel 10a.

At least two selected from among the fingerprint sensor 1610-1, the input sensor 1610-2, and the digitizer 1610-3 may be integrated into one sensing panel through substantially the same processes. If (e.g., when) the sensors as described in one or more embodiments are integrated as one sensing panel, the sensing panel may be arranged between the display panel 10a and a window arranged above the display panel 10a. According to one or more embodiments, the sensing panel may be arranged on the window, and the location of the sensing panel is not particularly restricted.

At least one selected from among the fingerprint sensor 1610-1, the input sensor 1610-2, and the digitizer 1610-3 may be built into the display panel 10a. For example, through the process of forming or providing the devices included in the display panel 10a (e.g., light-emitting device, transistor, and/or the like), at least one selected from among the fingerprint sensor 1610-1, the input sensor 1610-2, and the digitizer 1610-3 may be concurrently (e.g., simultaneously) formed or arranged.

The sensor module 1610 may be to generate an electrical signal or data value corresponding to an internal status and/or external status of the electronic device 1000. The sensor module 1610 may include, for example, a gesture sensor, a gyro-sensor, a pressure sensor, a magnetic sensor, an acceleration sensor, a grip sensor, a proximity sensor, a color sensor, an infrared (IR) ray sensor, a vivo sensor, a temperature sensor, a humidity sensor, and/or an illuminance sensor.

The antenna module 1620 may include one or more antennas to transmit or receive signals or power to or from the outside. According to one or more embodiments, the communication module 1730 may be to transmit the signal to an external electronic device or receive the signal from the external electronic device via an antenna that is suitable for the communication method. The antenna pattern of the antenna module 1620 may be integrated with one component (e.g., the display panel 10a or the input sensor 1610-2) of the display device 10.

The sound output module 1630 may be a device to output an acoustic signal to the outside of the electronic device 1000 and may include, for example, a speaker used for general purpose, such as multimedia and/or recording playback, and/or a receiver used exclusively for call reception. According to one or more embodiments, the receiver may be formed or arranged integrally with or separately from the speaker. A sound output pattern of the sound output module 1630 may be integrated with the display device 10.

The camera module 1710 may be to capture still images and/or videos. According to one or more embodiments, the camera module 1710 may include one or more lenses, an image sensor, or an image signal processor. The camera module 1710 may include an infrared ray camera that may be to measure whether there is a user, location of the user, eyes of the user, and/or the like.

The light module 1720 may be to provide light. The light module 1720 may include a light-emitting diode and/or a xenon lamp. The light module 1720 may be to operate in conjunction with the camera module 1710 or may be to operate independently.

The communication module 1730 may be to support establishment of wired communication channel and/or wireless communication channel between the electronic device 1000 and an external electronic device 1020 and communication performed through the established communication channel. The communication module 1730 may include one or all of a wireless communication module, such as a cellular communication module, a short-range wireless communication module, and/or a global navigation satellite system (GNSS) communication module, and a wired communication module, such as a local area network (LAN) communication module and/or a power line communication module. The communication module 1730 may be to communicate with the external electronic device 1020 via the short-range communication network, such as Bluetooth, WiFi direct, and/or infrared data association (IrDA), and/or a long-distance communication network, such as cellular network, Internet, and/or computer network (e.g., LAN and/or WAN). The one or more suitable types (kinds) of communication modules 1730 as described in one or more embodiments may be implemented in one chip or separate chips, respectively.

The input module 1300, the sensor module 1610, the camera module 1710, and/or the like may be linked with the processor 1100 and used to control operations of the display device 10.

The processor 1100 may be to output commands or data to the display device 10, the sound output module 1630, the camera module 1710, or the light module 1720 based on input data received from the input module 1300. For example, the processor 1100 may be to generate image data corresponding to the input data applied through a mouse and/or an active pen and output the image data to the display device 10 or may be to generate command data in correspondence with the input data and output the command data to the camera module 1710 or light module 1720. If (e.g., when) input data is not transmitted for a certain (e.g., set or predetermined) period of time from the input module 1300, the processor 1100 may switch the operation mode of the electronic device 1000 into a low-power mode or sleep mode so as to reduce the power consumption of the electronic device 1000.

The processor 1100 may be to output commands or data to the display device 10, the sound output module 1630, the camera module 1710, or the light module 1720 based on sensing data received from the sensor module 1610. For example, the processor 1100 may be to compare verification data applied by the fingerprint sensor 1610-1 with verification data stored in the memory 1200, and then, may be to execute an application according to the comparison result. The processor 1100 may be to execute commands or may be to output corresponding image data to the display device 10 based on the sensing data sensed by the input sensor 1610-2 or digitizer 1610-3. If (e.g., when) the sensor module 1610 includes a temperature sensor, the processor 1100 may receive temperature data regarding the measured temperature from the sensor module 1610 and may further carry out luminance correction and/or the like on the image data based on the temperature data.

The processor 1100 may be to receive measurement data as to whether there is a user, location of the user, eyes of the user, and/or the like from the camera module 1710. The processor 1100 may further be to carry out luminance correction and/or the like on the image data based on the measurement data. For example, the processor 1100 may be to determine whether there is the user from the input from the camera module 1710, and then, the processor 1100 may be to output image data of which the luminance is corrected through the data conversion circuit 1120-2 or gamma correction circuit 1120-3 to the display device 10.

One or more selected from among the components as described in one or more embodiments may be coupled mutually and communicate signals (e.g., commands or data) therebetween via an inter-peripheral communication scheme, e.g., a bus, general purpose input and output (GPIO), serial peripheral interface (SPI), mobile industry processor interface (MIPI), and/or ultra-path interconnect (UPI). The processor 1100 may be to communicate with the display device 10 via an agreed interface, e.g., any one selected from among the communication methods as described in one or more embodiments, but the communication method is not limited to the communication method as described in one or more embodiments.

The electronic device 1000 according to one or more embodiments may be one or more suitable types (kinds) of devices. The electronic device 1000 may include, for example, at least one of a portable communication device (e.g., smartphone), a computer device, a portable multimedia device, a portable medical device, a camera, a wearable device (e.g., watch), or a home appliance. The electronic device 1000 according to one or more embodiments of the present disclosure is not limited to the devices as described herein.

In one or more embodiments, the display device 10 may include the display panel 10a and the scan driver 150. The controller 1120-1 may be to generate a scan input signal that is necessary or desired to drive the scan driver 150. The power module may be to generate a scan input voltage that is necessary or desired to drive the scan driver 150 according to the control from the processor or controller 1120-1. For example, the scan input voltage may be a gate driving voltage.

The display panel 10a may be partitioned into the display area DA in which pixel circuits are arranged, and the peripheral area PA around the display area DA. As described in one or more embodiments, the area to display images may be the display area DA, and the area other than the display area DA, which does not display images, may be the peripheral area PA. Herein, the peripheral area PA may be referred to as a non-display area NDA.

The scan driver 150 may be arranged in the peripheral area and may be to receive the scan input signal from the controller 1120-1 and may be to receive the scan input voltage from the power module. The scan driver 150 may be to generate a scan signal or output the scan signal based on the scan input signal and/or the scan input voltage. The scan signal may be transferred from the scan driver 150 to the pixel circuit.

In one or more embodiments, the scan driver 150 may include at least one capacitor. The at least one capacitor may include one electrode and the other electrode. For example, the one electrode may be a signal line to transfer at least one of the scan input signal or the scan input voltage. For example, the one electrode may be at least a part of the signal line to transfer at least one of the scan input signal or the scan input voltage. The signal line may be, for example, a wiring to transfer the scan input voltage.

For example, the other electrode may overlap the one electrode. The other electrode may overlap the signal line that transfers at least one of the scan input signal or the scan input voltage. For example, the other electrode may overlap at least a part of the signal line to transfer at least one of the scan input signal or the scan input voltage.

In one or more embodiments, the peripheral area PA may include a wiring arrangement area in which interconnections are arranged, and a circuit arrangement area in which at least one transistor is arranged between the display area DA and the wiring arrangement area. For example, the at least one capacitor may be arranged in the wiring arrangement area.

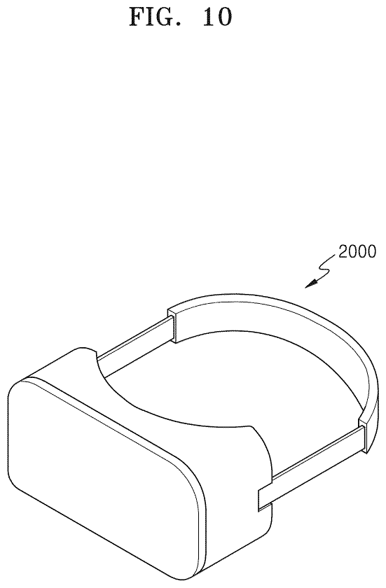

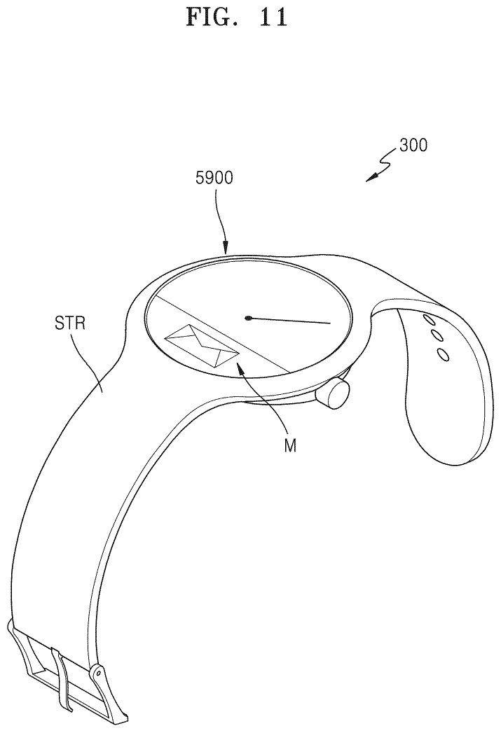

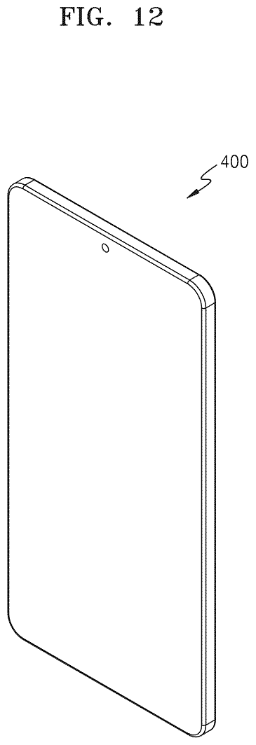

FIG. 10 is a perspective view schematically illustrating an example of an electronic device including the display device according to one or more embodiments of the present disclosure, FIG. 11 is a perspective view schematically illustrating another example of an electronic device including the display device according to one or more embodiments of the present disclosure, and FIG. 12 is a perspective view schematically illustrating another example of an electronic device including the display device according to one or more embodiments of the present disclosure.

Referring to FIG. 10, an electronic device 2000 including a display device may be implemented as, for example, a head mounted display (HMD). The electronic device 2000 may include a display unit, a main body, and an attachment portion.

For example, the display unit 2010 may include the display device 10 according to one or more embodiments as illustrated in FIG. 1 and may implement a screen. The main body 2020 may include a controller to apply a scan signal and a data signal to the display unit 2010, a touch sensor, an acoustic sensor, and/or the like. The electronic device 2000 may be worn on a user via the attachment portion 2030.

Referring to FIG. 11, an electronic device including a display device may be, for example, a wearable electronic device 300, for example, a smart watch.

The wearable electronic device 300 may include a main body 5900 and a fixing portion (STR). The main body 5900 may be to display an image M indicating certain information.

The image M may be implemented through the display device 10 as described in one or more embodiments, for example, may be implemented by light emitted from one or more light-emitting regions. Also, a region that displays the image M may include a region that senses a user's touch, for example, a region in which a touch sensing unit having a touch electrode is arranged. As such, the user may identify the image M on the main body 5900 while wearing or carrying the wearable electronic device 300 and may perform an input operation via direct user input or an input through a touch pen. In one or more embodiments, the main body 5900 may include the display device 10.

The image M may be to display, for example, an icon or an execution screen of an application that is being executed by an application processor, as well as an image that implements an analog clock including clock hands that represent current time.

The main body 5900 may be detachably coupled to the fixing portion STR. The user may wear the fixing portion STR in order to use the wearable electronic device 300 on his/her wrist. The fixing portion STR may be provided in a strap type (kind), but embodiments of the present disclosure are not limited to the purpose of being worn on the wrist of the user. The fixing portion STR may have a shape to be worn on the user's arm or around the user's neck or may be replaced with a cradle to attach the main body 5900 to another electronic device.

Referring to FIG. 12, the electronic device 400 including the display device may include, for example, a smartphone. The electronic device 400 that is a smartphone may be of one or more suitable types (kinds), e.g., a rigid type (kind), a bending type (kind) of which one or both (e.g., simultaneously) sides (e.g., opposite sides) are bent, or a foldable type (kind) that is folded at least once.

However, the electronic device is not limited to the foregoing examples. For example, the electronic device 400 may be any suitable electronic device 400 including the display device, such as a virtual reality (VR) device, a mobile phone, a smartphone, a tablet computer, a digital television (TV), a 3D TV, a personal computer (PC), a home appliance, a wearable device (e.g., watch), a laptop computer, a personal digital assistant (PDA), a portable multimedia player (PMP), a digital camera, a music player, a portable game console, a navigation device, and/or the like.

According to the present disclosure, a light-emitting efficiency of a display device may be improved or enhanced. For example, the light-emitting efficiency of the display device may be improved or enhanced through the enhanced design and material composition of the thin film encapsulation structure. For example, the buffer layer, which includes a multi-layered configuration or arrangement of SiOₓC_{y}H_{z}, may be engineered to balance mechanical flexibility and optical performance. The intermediate carbon-rich layer within the buffer structure may enhance planarization and reduce surface defects, while the outer carbon-lean layers improve or enhance adhesion to adjacent layers and minimize or reduce outgassing during processing. This layered architecture not only protects the underlying emission layers from environmental degradation but also contributes to improved or enhanced light transmission characteristics.

Furthermore, the gradual increase in refractive index across the buffer layer, from the first layer to the third layer, facilitates more efficient light extraction by reducing internal reflection losses. This optical gradient helps guide light generated by the emission layer toward the viewer-facing side of the display, thereby enhancing brightness and color fidelity.

Also, the inclusion of a protective layer between the emission layer and the buffer layer, composed of materials having tailored refractive indices and moisture/oxygen shielding properties, further supports efficient light emission and long-term reliability. The optional integration of organic and inorganic encapsulation layers above the barrier layer provides additional environmental protection and mechanical stability, ensuring that the display maintains high performance even under prolonged operational or environmental stress.

Collectively, these structural and material innovations contribute to a display device that exhibits superior light-emitting efficiency, improved or enhanced durability, and enhanced visual quality, making it well-suited for next-generation electronic applications.

The light-emitting element, the display apparatus/device, the electronic apparatus/device, the manufacturing apparatuses thereof, or any other relevant apparatuses/devices or components according to one or more embodiments of the present disclosure may be implemented utilizing any suitable hardware, firmware (e.g., an application-specific integrated circuit), software, or a combination of software, firmware, and hardware. For example, the one or more components of the device may be formed or provided on one integrated circuit (IC) chip or on separate IC chips. Further, the one or more components of the device may be implemented on a flexible printed circuit film, a tape carrier package (TCP), a printed circuit board (PCB), or formed or provided on one substrate. Further, the one or more components of the device may be a process or thread, running on one or more processors, in one or more computing devices, executing computer program instructions and interacting with other system components for performing the one or more suitable functionalities as described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

While certain embodiments of the present disclosure have been described and illustrated herein, a person having ordinary skill in the art to which the present disclosure pertains shall appreciate that there may be one or more suitable modifications and permutations of the present disclosure without departing from the spirit and scope of the present disclosure that are defined in the appended claims and equivalents thereof. Moreover, it shall be appreciated that the disclosed embodiments are not intended to restrict the aspects and features of the present disclosure thereto and that the technical ideas and aspects of the present disclosure are interpreted to be included within the scope of the appended claims and their equivalents.

What is claimed is:

1. A display device comprising:
a substrate;
a thin film transistor on the substrate;
a display element electrically connected to the thin film transistor; and
a thin film encapsulation layer on the display element, the thin film encapsulation layer comprising a buffer layer and a barrier layer that are sequentially stacked,
the buffer layer comprising a material having a composition of SiOₓC_{y}H_{z} (x>0, y>0, and z>0), and
a thickness of the barrier layer being greater than a thickness of the buffer layer.

2. The display device as claimed in claim 1, wherein:
the thickness of the buffer layer is 2000 Å to 5000 Å and the thickness of the barrier layer is 6000 Å to 1.5 μm.

3. The display device as claimed in claim 1, wherein:
the barrier layer is a single layer comprising at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

4. The display device as claimed in claim 1, wherein:
the buffer layer comprises a first layer, a second layer, and a third layer that are sequentially stacked, and
each of the first layer and the third layer has less content of carbon than the second layer.

5. The display device as claimed in claim 4, wherein:
a sum of a thickness of the first layer and a thickness of the third layer is less than a thickness of the second layer.

6. The display device as claimed in claim 4, wherein:
a sum of a thickness of the first layer and a thickness of the third layer is 30% or less of the thickness of the buffer layer.

7. The display device as claimed in claim 1, wherein:
the display element comprises a first electrode, a second electrode opposite to the first electrode, and an intermediate layer comprising an emission layer between the first electrode and the second electrode, and
the second electrode comprises a single layer of a transmissive electrode comprising at least one selected from among indium zinc oxide (IZO), indium tin oxide (ITO), and indium gallium zinc oxide (IGZO).

8. The display device as claimed in claim 7, wherein:
the second electrode has a thickness of 800 Å to 1200 Å.

9. The display device as claimed in claim 1, further comprising:
a protective layer between the display element and the buffer layer, the protective layer comprising at least one selected from among α-NPD, NPB, TPD, m-MTDATA, Alq₃, and CuPc.

10. The display device as claimed in claim 1, wherein:
the thin film encapsulation layer further comprises an organic encapsulation layer and an inorganic encapsulation layer, each being on the barrier layer, and
the inorganic encapsulation layer contacts an upper surface of the barrier layer on an outside of the organic encapsulation layer.

11. A display device comprising:
a substrate;
a thin film transistor on the substrate;
a display element electrically connected to the thin film transistor; and
a thin film encapsulation layer on the display element,
the thin film encapsulation layer comprising a buffer layer and a barrier layer that are sequentially stacked,
the buffer layer comprising a material having a composition of SiOₓC_{y}H_{z} (x>0, y>0, and z>0),
the buffer layer comprising a first layer, a second layer, and a third layer that are sequentially stacked, and
the second layer having a greater content of carbon than each of the first layer and the third layer.

12. The display device as claimed in claim 11, wherein:
a composition of the buffer layer is discontinuously changed at a boundary between the first layer and the second layer and a boundary between the second layer and the third layer.

13. The display device as claimed in claim 11, wherein:
a sum of a thickness of the first layer and a thickness of the third layer is less than a thickness of the second layer.

14. The display device as claimed in claim 13, wherein:
the sum of the thickness of the first layer and the thickness of the third layer is 30% or less of a thickness of the buffer layer.

15. The display device as claimed in claim 11, wherein:
a thickness of the buffer layer is 2000 Å to 5000 Å and a thickness of the barrier layer is 6000 Å to 1.5 μm.

16. The display device as claimed in claim 11, wherein:
the barrier layer is a single layer comprising at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

17. The display device as claimed in claim 11, wherein:
the display element comprises a first electrode, a second electrode opposite to the first electrode, and an intermediate layer comprising an emission layer between the first electrode and the second electrode, and
the second electrode comprises a transmissive electrode single layer comprising at least one selected from among indium zinc oxide (IZO), indium tin oxide (ITO), and indium gallium zinc oxide (IGZO).

18. The display device as claimed in claim 17, wherein:
the second electrode has a thickness of 800 Å to 1200 Å.

19. The display device as claimed in claim 11, further comprising:
a protective layer between the display element and the buffer layer, the protective layer comprising at least one selected from among α-NPD, NPB, TPD, m-MTDATA, Alq₃, and CuPc.

20. An electronic device comprising:
a controller configured to generate a scan input signal;
a power module configured to generate a scan input voltage; and
a display device configured to display images,
wherein the display device comprises:
a substrate;
a thin film transistor on the substrate;
a display element electrically connected to the thin film transistor; and
a thin film encapsulation layer on the display element, the thin film encapsulation layer comprising a buffer layer and a barrier layer that are sequentially stacked,
the buffer layer comprising a material having a composition of SiOₓC_{y}H_{z} (x>0, y>0, and z>0), and
a thickness of the barrier layer being greater than a thickness of the buffer layer.
